(19) United States
(12) Patent Application Publication
(10) Pub. No.: US 2010/0044738 A1
(43) Pub. Date: Feb. 25, 2010

(54) PREPARATION OF ORGANIC LIGHT EMITTING DIODES BY A VAPOUR DEPOSITION METHOD COMBINED WITH VACUUM LAMINATION

(75) Inventors: Georg Friedrich Gaertner, Aachen (DE); Herbert Friedrich Boerner, Aachen (DE)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/595,641

(22) PCT Filed: Apr. 17, 2008
(86) PCT No.: PCT/IB2008/051468

§ 371 Date: Oct. 13, 2009

(30) Foreign Application Priority Data
Apr. 20, 2007 (EP) 07106633.6

(51) Int. Cl. H01L 51/52; H01L 51/56

(52) U.S. Cl. 257/98; 438/29; 257/E21.211; 257/E51.018

(57) ABSTRACT

A method of fabricating an organic light emitting diode (OLED) is disclosed, which reduces the formation of physical defects in the GLED, comprising the removal of dust particles from a first and a second substrates (40, 90), separately coating the first and the second substrate using a vapour deposition method (50, 80) and laminating the first and the second substrate together in vacuum.

### FIELD OF INVENTION

The present invention relates to organic light emitting diodes (OLEDs), and more specifically to a method of fabricating the same, which reduces the formation of physical defects in the OLED.

### BACKGROUND OF THE INVENTION

An organic light emitting diode (OLED) typically consists of an organic light-emitting layer and additional organic layers on both sides of the light-emitting layer, which facilitate the charge transport and comprise an hole transport layer and an electron transport layer. The organic layers are sandwiched between two electrode layers, an anode layer and a cathode layer, both of which are covered on one side with a substrate for protection and stability.

Conventionally, OLEDs are produced by vapour deposition of the electrode layers and organic layers performed in high or ultra-high vacuum. While this technology offers certain advantages with regard to the thickness control of each layer as well as sufficient purity of the materials and good adherence of the layers, one of the critical drawbacks is the occurrence of physical defects due to the presence of extraneous unwanted material disposed during formation of the constituent layers of the OLED structure. The defects may be in the order of several nanometers to micrometers in diameter and can spread from the cathode region of the OLED into regions that carry current. As a result a short-circuit may occur, or the defects may form pinholes leading to penetration of oxygen and moisture resulting in non-operative, i.e. dark, areas due to corrosion and destroying the emission capability of the OLED. This so-called “dark spots” are a common problem, and are often attributable to the presence of dust particles.

Wet coating technologies such as spin coating are widely used in polymer based light emitting diodes, but have the disadvantage of insufficient multilayer capability.

Very rarely used are printing, stamping or lamination methods, e.g. screen-printing, inkjet printing, hot microprint contact, or micro stamping, which currently show only minor performance data. Assembling of separately produced OLED layer structures using pressing or stamping is described in the publication “Effects of dust particles and layer properties on organic electronic devices fabricated by stamping” of Cao et al. (J. Appl. Phys. 98, 0033713 (2005)) and in “Patterning of active organic materials by direct transfer for organic electronic devices” of Kim et al. (J. Appl. Phys. 97, 113512 (2005)). The described methods can be used to stamp patterns, wherein a metal layer is coldly welded onto a thin metal layer and remains on the counter substrate via a low adherent interface layer (Cao et al.), or wherein an organic hole transport layer is pressed onto an equal layer (Kim et al.). According to these documents the use of elastic stamps leads to better envelopment of dust particles compared to rigid stamps. However, these methods are performed under ambient air. Further, OLEDs manufactured according to these methods have several drawbacks such as increased power consumption and adherence problems between different organic layers.

The publication “High performance organic light emitting diodes fabricated via a vacuum-free lamination process” of Lui et al. (Appl. Phys. Lett. 88, 223509 (2006)) relates to a method for assembling separately produced anode and cathode components using rolling lamination. For manufacture of an electron conductor said method is combined with n-doping of an organic light emitting polymer with an alkali metal. The experiments were carried out in an Argon atmosphere containing less than 5 ppm oxygen or water, however, the mechanical adherence was low and the layers could be delaminated very easily.

### SUMMARY OF THE INVENTION

It would be advantageous to provide a fabrication method for OLEDs that reduces the formation of physical defects in the constituent layers of the OLED structure. Currently, the vast majority of OLEDs is produced by vapour deposition methods performed in high or ultra-high vacuum. A common problem of these methods is the inclusion of extraneous unwanted material, in particular dust particles, during formation of the OLED layers. The included material can exhibit sharp edges or can cause defects in the layer structure which may propagate to the subsequent layers of the OLED. This can result in a short-circuit or the formation of pinholes and penetration of oxygen and moisture, which will reduce the lifetime of the OLED. It would be desirable to provide a fabrication method of an OLED, wherein the cathode layer of the OLED remains intact. It would be also desirable to provide a fabrication method of an OLED, wherein the number of pinholes is strongly reduced. Furthermore, it would be desirable to provide an OLED with an enhanced lifetime.

To better address one or more of these concerns, in a first aspect of the invention a fabrication method for an OLED is provided that reduces the inclusion of extraneous unwanted material into an OLED layer.

The transport layers of an OLED do not only function as transport medium but also in some case function as buffers preventing humidity and oxygen to diffuse into the active emitting layer. Consequently, the design of the different OLED layers and the order in which they are placed can also affect the lifetime of an OLED. Thus, it would be advantageous to provide a fabrication method that provides better multilayer structures. Further, it would be desirable to provide a fabrication method that reduces the propagation of defects in the layer structure to the subsequent layers.

To better address these concerns, in another aspect of the invention a method for laminating separately produced OLED structures together is provided.

In a further aspect of the invention an OLED is provided, wherein the adherence between the laminated OLED layers is improved.

In a still further aspect, an OLED is provided having improved electrical properties.

These and other aspects of the present invention will be apparent from and elucidated with reference to the embodiments described hereinafter.

### BRIEF DESCRIPTION OF THE DRAWINGS

FIG. 1 shows cathode and anode substrates separately and assembled as OLED device.

FIG. 2 shows a an aluminum foil as cathode substrate and a anode substrate separately and assembled as OLED structure.

FIG. 3 shows an electrically conductive soft material and a anode substrate with a cathode layer separately and assembled as OLED structure.

The term “dust particle” as used herein means any extraneous unwanted material in an OLED structure.

### DETAILED DESCRIPTION OF EMBODIMENTS

In one embodiment of the invention a method of fabricating an OLED is provided

comprising the steps of providing a first and a second substrates, removing dust particles from said substrates, separately coating the first and the second substrate by a vapour deposition method, and laminating the first and the second substrates together under vacuum.

The dust particles on said substrates can be removed to a large extent by several methods or a combination thereof. In one exemplary embodiment the dust particles can be removed by megasonic or ultrasonic cleaning, for example, in ultrapure water. In another exemplary embodiment the dust particles can be removed by charging the dust particles and removing at least a part of the charged dust particles in an electric field.

In an exemplary embodiment the dust particles can be negatively charged using an electron beam that can be generated, for example, by a differentially pumped electron gun, the gun being similar to guns used in a cathode ray tube. Differential pumping means that in the gun and around the cathode at least high vacuum, e.g. of <10⁻⁵ Pa, is maintained by continuous pumping (e.g. by a turbomolecular pump), whereas much higher pressures, e.g. of 10 to 200 Pa, can be applied in a laminar inert gas flow around the substrate. Typically a high pressure gradient will be obtained in the region of the small aperture/hole for the electron beam

In an exemplary embodiment, the electric field can be a homogeneous electric field of about 30 to about 100 V/cm and can be generated, e.g., by a dc power supply and applied to two electrically conducting plates forming a capacitor. The substrates can be placed in between the two electrically conducting plates after charging, for example, with the substrate base touching the cathode and the substrate surface with the charged particles being exposed to the field directed to the anode. The anode plate can be cleaned after the whole process by standard methods, or in appropriate intervals.

In a further exemplary embodiment the cathode plate is heated to an elevated temperature, e.g., to about 150-220° C. Optionally, this exemplary embodiment can be combined with the previous exemplary embodiment.

In still a further exemplary embodiment an inert gas flow, e.g., a constant laminar inert gas flow at low pressures helps to loosen the particles from the substrate and collect them on the anode. Suitable inert gases include, e.g., nitrogen, argon or other noble gases.

In still a further exemplary embodiment a temperature gradient is applied to the substrates, wherein the temperature gradient is especially effective at the surface of the substrate and may have an upper temperature limit of about 200° C., and the substrate surface is exposed to a laminar flow of inert gas.

In an other embodiment the dust particles can be removed by exposing said substrates to a separately generated plasma, e.g. a microwave or RF plasma, wherein the dust particles on the substrate surface are charged in a reactive gas, and are collecting the charged dust particles in a particle collector. A suitable reactive gas, for example, is SiH₄. The reactive gas may flow above the substrate in a laminar flow. Loosened dust particles down to 10 nm size can be collected, e.g., in a negatively charged fine particle collector consisting of a tube with ceramic outside walls and an inner anode.

In still another embodiment laser evapouration can be used to remove dust particles from the substrate surface which are embedded in an evapourable thin fluid film covering the substrate surface. The dust particles will be entrained in the vapour and can then be collected from the gas downstream.

The substrates are typically coated by a vapour deposition method. For example thermal evapouration in high or ultrahigh vacuum can be used, which consists in heating until evapouration of the material to be deposited in form of a thin film on the cold substrate surface. Suitable methods for applying heat to the material are, for example, resistance heating, wherein the material is heated until fusion by means of an electrical current passing through a filament or metal plate, or bombardment with a high energy electron beam from an electron beam gun.

The separately coated substrates are assembled to an OLED structure by laminating the first and the second substrate together under vacuum. The lamination can be performed, for example, using a roll laminator or an laminating machine comprising an elastomeric soft stamp, which, e.g., can be made from silicon rubber or another elastomer. Typically a continuous pressure increase from 0.01 to 0.6 MPa may be applied. Furthermore, the lamination can be carried out at room temperature or can be performed at elevated temperatures, which can enhance the adherence of the laminated substrates. Suitable temperatures for the lamination process are between about 20° C. and about 100° C., or between about 70 and about 80° C., depending on the glass transition temperature of the organic layers; which may no be exceeded.

In an exemplary embodiment a stamp on polydimethyl siloxane (PDMS) basis with a Youngs modulus of around 3 MPa may be used.

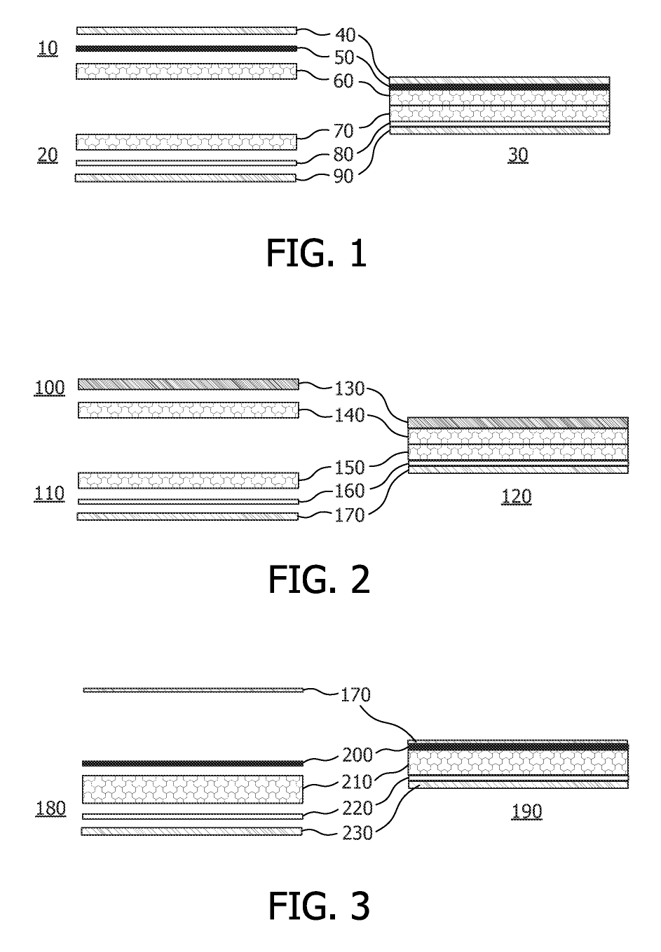

According to one embodiment an anode substrate 20 and a cathode substrate 10 are fabricated separately: A first substrate 90 is coated with an anode layer 80 and at least one organic layer 70, and a second substrate 40 is coated with a cathode layer 50 and at least one organic layer 60 as shown in FIG. 1. After laminating the anode substrate 20 and the cathode substrate 10 together the OLED layer structure 30 is obtained.

In an exemplary embodiment the anode substrate 20 and cathode substrate 10 can have the same organic layer at the top.

In another embodiment the second substrate coated with a cathode layer and at least one organic layer can include an aluminum foil coated with at least one organic layer. FIG. 2 shows an anode substrate 110 comprising a first substrate 170, an anode layer 160 and at least one organic layer 150, and as cathode substrate 100 an aluminum foil 130 coated with at least one organic layer 140. After laminating the anode substrate 110 and the coated aluminum foil 100 together the OLED layer structure 120 is obtained.

In an exemplary embodiment the aluminum foil can be flexible, and can be sealed on the backside, for example, with a polymer film. In another exemplary embodiment the aluminum foil 130 is coated with the same organic layer 150 as the anode substrate 110.

According to another embodiment only the first substrate 230 is coated as illustrated in FIG. 3. The coated substrate 180 comprises an anode layer 220, at least one organic layer 210 and a cathode layer 200, and the second, uncoated substrate 170 comprises an electrically conductive soft material. After laminating the coated substrate 180 and the uncoated substrate 170 together the OLED layer structure 190 is obtained.

In an exemplary embodiment the first and the substrate is rigid. In another exemplary embodiment the first substrate is rigid and the second substrate is flexible or vice versa. In still another exemplary embodiment the first and the second substrate is flexible.

The provided substrates may be transparent or opaque depending on the side of the OLED that let pass the emitted light. Suitable substrates, for example, can be made from glass such as borosilicate glass or sodalime glass. Other suitable materials are, for example, polymers or plastics such as polycarbonate, polyethylene terephthalate, polyacrylates, polymethacrylates, polysulfones and the like. The substrates can also be made from silicon such as amorphous silicon, polycrystalline silicon, single crystal silicon and the like. Another class of materials that, for example, can be used are metal foils or metallized polymers. Other materials can also be selected provided that the materials can effectively support the other layers, and do not interfere with the OLED functional performance.

The anode layer can comprise suitable positive charge injecting materials such as indium tin oxide (ITO), silicon, tin oxide, and metals with a high work function such as gold, platinum or palladium. Other suitable materials can be, for example, electrically conductive carbon, π-conjugated polymers such as polyaniline, polythiophene, polypyrrole and the like. The cathode layer can comprise suitable electron injection materials, for example, metals with a low work function such as aluminum, barium, calcium, indium, lithium, magnesium, silver and their alloys. The electrode layers may be transparent or opaque depending on the side of the OLED that let pass the emitted light.

The organic layers can comprise hole injection layers, hole transport layers, emission layers, hole blocking layers, electron transport layers, or electron injecting layers. Hole injection layers, which accept holes from the anode and transport them to the hole transport layer, can be made, for example, from porphyrinic compounds such as copper phthalocyanine (CuPc), zinc phthalocyanine, acid doped poly(ethylenedioxythiphene), or acid doped polyaniline. Hole transport layers transport holes from the anode layer to the emitting layer, and can be selected, for example, from triarylamines such as 4,4′,4″-tri(N-phenothiazinyl)triphenylamine (TPTTA), 4,4′,4″-tri(Nphenoxazinyl)triphenylamine (TPOTA), N,N′-bis(3-methylphenyl)-N,N′-diphenyl benzidine (TPD), or polyvinyl carbazole. Emission layers facilitate the charge recombination, i.e. the light generation, and contain luminescent material in an electronically suitable matrix. Examples of luminescent materials are coumarin, dicyanomethylene pyranes, polymethine, oxabenzanthrane, xanthene, pyrylium, carbostyl, perylene, quinacridone dyes, fused ring fluorescent dyes such as perylene, rubrene, anthracene, coronene, phenanthrecene, or pyrene, butadienes such as 1,4-diphenylbutadiene and tetraphenylbutadiene, stilbenes and phosphorescent complexes like Iridium(III)(phenyl-pyridine)₃. Hole blocking layers prevent diffusion of holes into the electron transport layer and can be made, for example, from 2,9-dimethyl-4,7-diphenylphenanthroline. Electron transport layers, which facilitate the movement from electrons from the cathode layer to the emitter layer, can be made, for example, from metal chelates of 8-hydroxyquinoline such as tris(8-hydroxyquinolinato)aluminium (Alq₃), or oxadiazoles. Electron injecting layers accept electrons from the cathode layer and transmit them to the electron transport layer, and can comprise, for example, metal fluorides such as LiF or CsF.

1. A method of fabricating an organic light-emitting diode, comprising the steps of:
providing a first and a second substrate,
removing dust particles from at least one of said first and second substrates,
separately coating the first and the second substrate by a vapour deposition method, wherein the first substrate is coated with an anode layer and a first light-emitting layer thereover, the first light-emitting layer comprising an organic material and wherein the second substrate is coated with a cathode layer and a second light-emitting layer thereover, the second light-emitting layer comprising said organic material, and
laminating the first and the second substrate together under vacuum.

2. The method according to claim 1, wherein the removing of dust particles on said substrates includes charging the dust particles and removing at least a part of the charged dust particles in an electric field.

3. The method according to claim 1, wherein the dust particles are removed by at least one of megasonic or ultrasonic cleaning in ultrapure water.

4. The method according to claim 1, wherein the removing of dust particles on said substrates includes exposing said substrates to a separately generated plasma, wherein the dust particles are charged in a reactive gas, and collecting the charged dust particles in a particle collector.

5. (canceled)

6. (canceled)

7. (canceled)

8. (canceled)

9. The method according to claim 1, wherein the substrates are laminated together using roll lamination.

10. The method according to claim 1, wherein the substrates are laminated together using elastic stamps.

11. An organic light-emitting diode fabricated according to claim 1.
